(19) United States
(12) Patent Application Publication
(10) Pub. No.: US 2003/0023892 A1
(43) Pub. Date: Jan. 30, 2003

(54) Peer-to-peer redundancy control scheme with override feature

(76) Inventor: Chiazzese Giovanni, Pierrefonds (CA)

Correspondence Address: Jones, Day, Reavis and Pogue, North Point, 901 Lakeside Avenue, Cleveland, OH, 44114, US

(21) Appl. No.: 09/908,001

(22) Filed: Jul. 18, 2001

(51) Int. Cl. H03K 19/003

(52) U.S. Cl. 714/2

(57) ABSTRACT

A control system is provided for a network system having a plurality of redundant elements wherein each redundant element has an active state and a standby state. The control system comprises a peer-to-peer-like control system that is operative to select the active and standby states of the redundant elements and a central controller system that is operative to send messages to the peer-to-peer-like control system wherein the messages allow the central controller system to override the selection of states for the redundant elements made by the peer-to-peer-like control system.

This application claims the benefit under 35 U.S.C. §119(e) to copending U.S. Provisional Patent Application No. 60/220,256 entitled “Peer-to-Peer Redundancy Scheme With Software Override” and filed on Jul. 24, 2000. This application also incorporates copending U.S. Provisional Patent Application Nos. 60/220,256 by reference as if fully rewritten here.

### BACKGROUND

1. Technical Field

The claimed invention is directed to the field of redundancy control systems. More specifically, the invention provides a peer-to-peer-like redundancy control system having an override feature.

2. Description of the Related Art

Redundancy is a common need in many types of systems in order to increase the reliability of the system. For example, in a telecommunications network element having numerous network components or cards, it is common to provide redundant components in the event that if one of the components fails, another component can take its place, thus maintaining the operation of the network. In such systems, however, it is difficult to predict the behavior of a network component when it has failed.

One current redundancy scheme involves providing a peer-to-peer system in which two redundant units work cooperatively to determine which of the two redundant elements will be active wherein the remaining redundant element will be in an inactive or standby state. Each of the redundant units monitors the system for failures, and when a failure is sensed they communicate information to each other to effect the switching of the active unit to the standby mode and the inactive unit to an active mode. The peer-to-peer scheme does not require intervention from a third unit in order to effect the redundant switch over.

A second known method of controlling redundant hardware involves using a third device such as a control device that is coupled to both of the redundant units. The control device monitors the system and determines which of the two redundant units should be active and which should be in a standby mode.

### SUMMARY

In furtherance of the state of the art, provided is a control system for redundant elements that comprises a peer-to-peer-like control system for selecting which of the redundant elements should be in an active state and which should be in a standby state and a central control element. The central control element has the capability of passing messages to the redundant elements which allow the central control element to override the peer-to-peer-like control system and select which of the redundant elements should be in the active state and which should be in a standby state.

### BRIEF DESCRIPTION OF THE DRAWINGS

FIG. 1 is a block diagram of a preferred embodiment of the claimed redundancy control scheme; and

FIG. 2 is a state diagram that illustrates the preferred mode of operation for one of the redundant components in the claimed redundancy control scheme depicted in FIG. 1.

### DESCRIPTION OF EXAMPLES OF THE CLAIMED INVENTION

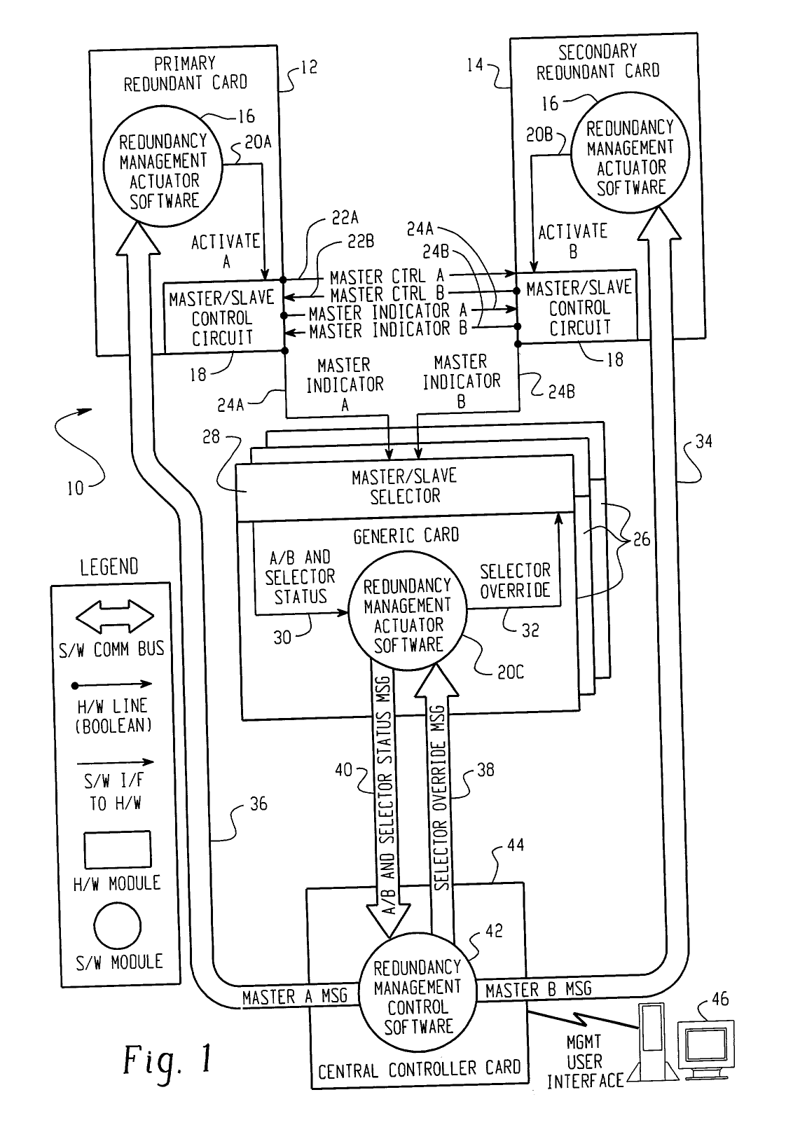

With reference to the drawing figures, FIG. 1 sets forth a block diagram that illustrates a preferred embodiment of a system 10 that utilizes the claimed redundancy control system. The system 10 preferably comprises a primary redundant component 12 and a secondary redundant component 14 wherein during normal operation one of the redundant components is in an active (or master) state and the other is in an inactive (or slave) state. The redundant components in this example are responsible for providing some function that other components 26 of the system 10 utilize. The system 10 has been shown in this embodiment to include one set of two redundant elements. It should be understood, however, that the system 10 is not limited to a single set of redundant components and it should also be understood that each set could comprise two or more redundant components. Each redundant component preferably comprises a redundancy control component that preferably further comprises redundancy management actuator software 16 and a master/slave control circuit 18. The redundancy control component for each redundant component preferably cooperates with the redundancy control component for the other redundant components in a peer-to-peer-like redundancy arrangement to determine which of the redundant components should be in the master state and which should be in a slave state. The redundancy control components also preferably cooperate with a central control element 44 to allow the control element 44 to determine which redundant component should be active and which should be in a standby state. The redundancy control systems preferably allow the central control element 44 to override the selection of states made through the peer-to-peer-like redundancy arrangement.

The claimed redundancy control system is preferably implemented in a telecommunications network element, such as a SONET add-drop multiplexer (ADM), although the methodology described herein could be utilized in any system requiring redundant operation. In a SONET ADM implementation, for example, the redundant components 12, 14 could be redundant cross-connect cards for switching telecommunication signals that are routed though the ADM. In the SONET ADM exemplary implementation, the central controller element 44 could be a master control unit (MCU), and the generic components 26 could be telecommunication line cards that are coupled to and communicate signals to and from the redundant cross-connect cards 12, 14.

An exemplary node element that, among other things, performs the functions of an ADM is the MCN 7000. The MCN 7000 is an advanced network element available from Marconi Communications. More details on the MCN 7000 are described in commonly-assigned U.S. patent application Ser. No. 09/875,723 entitled “System And Method For Controlling Network Elements Using Softkeys” which is incorporated herein by reference.

In the illustrated example of a SONET ADM implementation, each redundant component 12, 14 is preferably capable of providing protection if the other component is faulty and is also capable of being serviced (including an upgrade service) while the ADM is in-service in the field. In addition, each component 12, 14 preferably may be selected as the master or slave unit based on either a user initiated (MANUAL) selection or an AUTOMATIC selection as the result of the satisfaction of failure criteria. The MANUAL selection is usually initiated when maintenance procedures are required within the network element while the AUTOMATIC selection is usually initiated when the network element is protecting against faults. In addition, the AUTOMATIC selection may be initiated by the peer-to-peer system or by the control element 44.

In the system 10 shown in FIG. 1, the MANUAL selection of the master/slave states of each component 12, 14 by the user are preferably made via the central controller component 44, which is preferably coupled to an external management user interface 46. If the central controller component 44 is not present in the system 10, the redundant components 12, 14 are only capable of selecting states via the peer-to peer AUTOMATIC selection mechanism. Preferably, the peer-to-peer AUTOMATIC selection process may continue to operate when the central controller 44 is not present in the system 10 or inoperative. Alternatively, the AUTOMATIC selection mechanism may be INHIBITED when the central controller 44 is not present in the system 10 or inoperative. Also, the AUTOMATIC selection mechanism may optionally be INHIBITED when the central controller 44 is present in the system 10 and is operative.

The choice of when to INHIBIT the AUTOMATIC selection mechanism is preferably made by the user and preferably is independent from the MANUAL selection of the Master and Slave components. When the master/slave selection mechanism is INHIBITED, neither a MANUAL nor an AUTOMATIC selection may activate the component that is inhibited. Preferably, when the master/slave selection mechanism is not INHIBITED, an AUTOMATIC selection preempts a MANUAL selection, and a MANUAL selection may not preempt an AUTOMATIC selection. The AUTOMATIC selection mechanism becomes active when a failure of one of the redundant components 12, 14 is detected and declared. The card failure declaration may be triggered, for example, by the removal of one of the components 12, 14 from the system, or may be triggered by a failure signal provided by a software module monitoring the system.

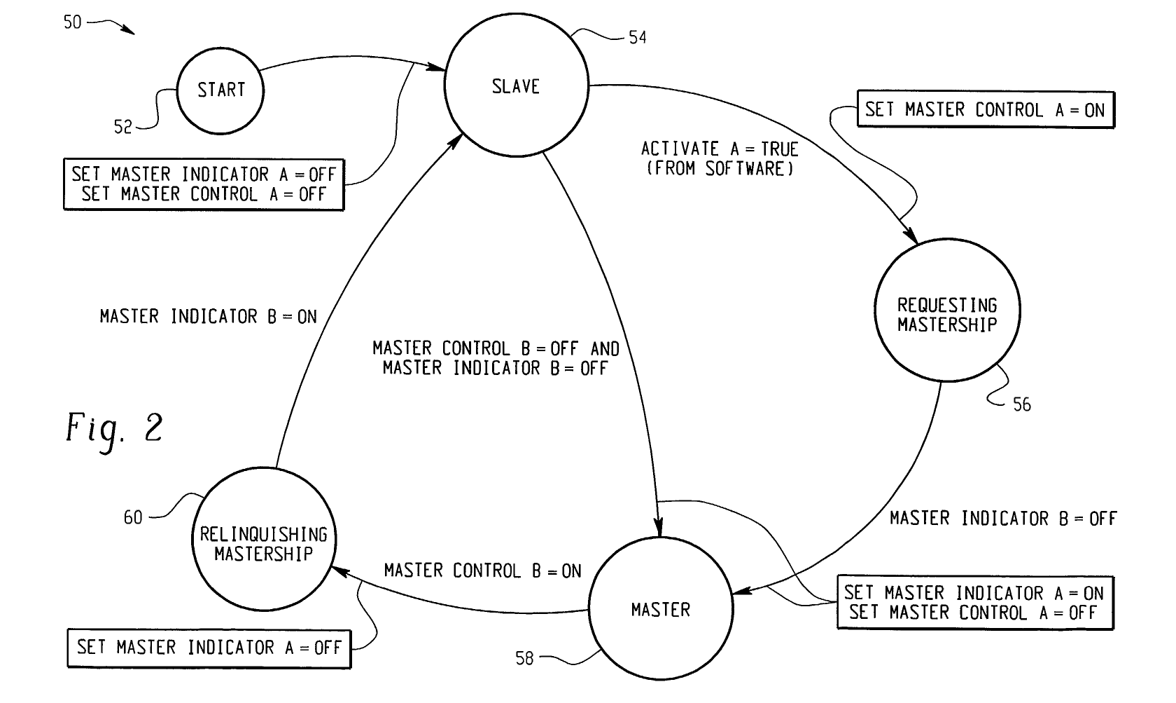

The master/slave control circuit 18 on each redundant component cooperates with the other master/slave control circuit 18 and with a master/slave selector 28 on each generic component 26 to form a peer-to-peer-like control system. There are preferably four control signals that are communicated between each master/slave control circuit 18: a master control A signal 22A, a master control B signal 22B, a master indicator A signal 24A, and a master indicator B signal 24B. The master control signals 22A, 22B are used to communicate a switch-over request from one component to the other. The master indicator signals 24A, 24B indicate which component is the master and which component is the slave (i.e., which component is in active mode and which component is in standby mode.) The operation of these control signals is described in more detail below with reference to FIG. 2.

The two master indicator signals, master indicator A 24A and master indicator B 24B, are also provided to each generic card 26. The master/slave selector circuit 28 on each generic card 26, depending on the state of the two indicators 24A, 24B, selects which redundant component the generic component 26 will recognize as the active redundant component and utilize. By examining the state of the indicators 24A and 24B, each generic component 26 can determine which redundant component 12 or 14 has been declared the master and as a result each generic component 26 can direct all of its requests for service to that same redundant component 12 or 14.

The system 10 shown in FIG. 1 also includes an override backup control mechanism. The override backup control mechanism preferably comprises the redundancy management actuator software 16 in each of the primary and secondary redundant components 12, 14, and in the plurality of generic components 26, redundant management control software 42 in the central control component 44, and a plurality of software communication bus structures 34, 36, 38, and 40.

The software communication bus structures 34, 36, 38, and 40 provide communication channels for communicating information and control settings between the primary and secondary redundant components 12, 14, the plurality of generic components 26, and the central controller component 44. Bus 36 is a master A message bus 36 for communicating information between the primary redundant component 12 and the central controller 44. Bus 34 is a master B message bus 34 for communicating information between the secondary redundant component 14 and the central controller 44. Bus 40 is an A/B selector status message bus 40 for communicating the selector status of the generic component 26 hardware selector 28 to the central controller component 44. Bus 38 is a selector override control bus 38 that is operative to transmit control signals from the central controller component 44 to the plurality of generic components 26 to override the master indicator signals 24A, 24B and independently control the hardware selector 28 on the generic components 26.

During normal operation of the redundancy control system shown in FIG. 1, the peer-to-peer-like control system (i.e., master/slave control circuits 18 and master/slave selectors 28) control the operation and selection of the active component and conversely the selection of the inactive component (i.e., master and slave selections). In the background, however, the redundancy management control software 42 is communicates with each of the primary and redundant components 12, 14 through the master A message bus 36 and the master B message bus 34, respectively, in order to determine if there has been a failure or some other abnormal condition that could render the peer-to-peer-like control system selection unreliable or uncertain.

If the central controller 44 determines that the peer-to-peer-like control system is not functioning properly or that some other abnormal condition has occurred, the central controller 44 can trigger the override mechanism to signal the redundant components 12, 14 to switch states, i.e., for the formerly inactive component to become active (switch to Master state) and for the formerly active component to become inactive (switch to Slave state). The controller 44 preferably signals the primary and secondary redundant components 12, 14 to switch states via the master A message bus 36 and the master B message bus 34, respectively. The redundancy management actuator software 16 in each of these components 12, 14 receives the message transmitted by the central controller 44 and switches the state of an activation line 20A, 20B, which in turn signals the master/slave control circuit 18 to switch states.

The central controller 44 also signals to the generic components 26 to select as the active component the redundant component that has been commanded by the central controller 44 to switch to the Master state. The central controller 44 preferably monitors A/B selector status messages from the generic components 26 via the bus structure 40, which report the state of the two indicator lines 24A, 24B, and consequently knows which redundant component 12, 14 the generic components 26 believe is in the active state. The Redundancy Management Actuator Software 20C on each generic component 26 preferably forwards information regarding the state of its associated master/slave selector 28 to the Redundancy Management Control Software 42 via bus structure 40. If the generic components 26 have not selected the redundant component that has been commanded to switch to the active state, the central controller 44 transmits selector override control messages to the hardware selectors 28 on the generic components 26 to signal the hardware selectors 28 to select the redundant component that has been commanded by the central controller 44 to switch to the active state. The central controller 44 preferably accomplishes this signaling through the redundancy management control software 42. The redundancy management control software 42 preferably transmits a selector override message via bus structure 38 to the redundancy management actuator software 20C in each generic component 26 which, in turn, transmits a selector override command 32 to the master/slave selector 28 which causes the master/slave selector 28 to select as the active component the redundant component that has been commanded by the central controller 44 to switch to the active state. As a result, in the case of a malfunction of the peer-to-peer-like control system, the central controller 44 can override the peer-to-peer-like control system by commanding the redundant components to switch states and signaling to the generic components which redundant component should be treated as the active component.

Therefore, in the preferred system, the peer-to-peer-like control system is the primary control mechanism for selecting the master/slave designations for the redundant components 12, 14. The controller 44, however, can generate an AUTOMATIC signal that can override the master/slave designations made by peer-to-peer-like control systems. The override command can be triggered, for example, if the controller 44 senses a component failure such as a failure in the master/slave control circuit 18. When such a failure is detected by the controller 44, the controller 44 can command the redundant components to switch states and command the generic components to use the newly activated redundant component.

Also, the non-presence of the central controller 44 does NOT require the redundancy mechanism to be shut down thereby providing better resiliency during network maintenance / upgrade procedures.

Referring now to FIG. 2, shown is a state diagram 50 that illustrates the preferred mode of operation of one of the redundant components, in this case the primary component 12, in the redundancy control system shown in FIG. 1. The operation of the secondary redundant component 14 is similar to the primary component 12 and hence will not be separately described. The state diagram 50 provides an example of the conditions necessary for a state change and the states in which a redundancy component could transition to based on actions initiated via the peer-to-peer-like control system and actions initiated via the override mechanism. In an override initiated switch, the redundant component 12 first requests mastership because the secondary component 14 is still the active component instead of immediately switching to a master state. As previously described, the switch message may be generated by a user as a MANUAL command, or as an override (i.e., AUTOMATIC command) from the central controller 44. In a peer-to-peer switch, the component 12 switches directly to the active state because the secondary component 14 has failed and can no longer be active.

The operation begins at state 52, for example, when power is applied to the system that contains the redundant components 12, 14. In this example, at power up, the master indicator A signal 24A and the master control A signal 22A are both set to an off state, thus causing the primary component 12 to be in the standby or slave state 54. From the slave state 54, there are two scenarios which could cause the redundant component 12 to transition to the master state 58.

When the first scenario occurs, shown on the right-hand side of the figure, the redundancy management actuator software 16 causes the activate A signal 20A to be in a true state and transmits this signal to the master/slave control circuit 18. When this happens, the primary component 12 enters the requesting mastership state 56, and requests mastership by causing the master control A signal 22A to be set to the on state. The master control A signal is provided to the master slave control circuit 18 of the secondary redundant component 14. If the secondary redundant component 14 responds by setting the master indicator B signal 24B to an off state, the primary component 12 will enter the master state 58, will set the master A indicator signal 24A to an on state, and set the master control A signal to an off state.

This type of switching may be initiated in response to the communication between the master/slave control circuit 18 of the two redundant components 12, 14 in the case of a MANUAL switch. Alternatively, this type of switching may be initiated in an Automatic override scenario in response to messages sent to the redundant components 12, 14 by the controller 44 along the buses 34, 36 when the failure of the master/slave control circuit 18 has been detected. If the master indicators 24A, 24B are not properly set to the correct state in response to changes in the activate control signals 20A, 20B, the central controller 44 can direct the generic components 26 to select the correct redundant component as the active component via selector override messages communicated over the bus structure 38.

The second scenario for causing the redundant component 12 to switch to the Master state occurs when the master control B signal 22B is set to an off state and the master indicator B signal 24B also is set to an off state. When this occurs the primary redundant component 12 immediately transitions to the Master state 58, without first entering the Requesting Mastership state 56. After reaching the Master state 58, the primary redundant component 12 switches the master indicator A signal 24A to an on state and switches the master control A signal 22A to an off state.

To request that the primary redundant component 12 transition from the Master state to the Slave state, the redundant component 14 must switch the master control B signal 22B to an on state. When the redundant component 12 senses that the master control B signal 22B is in the on state, the primary component 12 will transition to the relinquishing mastership state 60 and will switch the master indicator A signal 24A to an off state. After the master indicator B signal 24B is set to an on state, indicating that the secondary redundant component 14 has entered the master state 58, the primary component 12 will transition to the slave state 54.

Described next is the behavioral operation of the preferred master/slave control circuits 18 and the preferred master/slave selector circuit 28 during state transitions. With regard to the preferred master/slave control circuit 18, MANUAL selection of the primary component 12 as the master is accomplished in accordance with the rightmost path of the state diagram. The redundancy management actuator software 16 on the primary redundant component 12 receives a signal from the central controller 44 via the master A message bus structure 36 and transmits the activate signal 20A to the master/slave control circuit 18. As a result of receiving the activate signal 20A, the master/slave control circuit causes the primary component 12 to enter the requesting mastership state 56.

If one of the redundant components 12, 14 is removed from the system, the remaining redundant component will sense that the master control signal and master indicator signal associated with the removed redundant component are in the off state. Setting the signals to an off state when the associated card is removed can be accomplished using various methods such as through appropriate circuitry on the backplane or appropriate circuitry on the remaining redundant component. As a result, as illustrated in FIG. 2, the remaining redundant component will transition directly from the slave state 54 to the master state 58 when the other redundant component is removed from the system.

The master/slave selector circuit 28 in each generic component 26 preferably will select the active component for use in accordance with the table set forth below. The primary and secondary redundant components 12, 14, preferably provide each generic component 26 with the master indicator signals 24A, 24B. The central control component 44 preferably provides each generic component 26 with the selector override signal 32 via the redundancy management actuator software 20C and the selector override message, which is transmitted to the generic components 26 via the selector override message bus structure 38.

| | Master | Master | |
|---|---|---|---|
| Selector Override | Indicator A | Indicator B | Resulting Selection |
| PRIMARY | X (don't care) | X (don't care) | PRIMARY |
| SECONDARY | X (don't care) | X (don't care) | SECONDARY |
| NO OVERRIDE | On | On | PRIMARY (this is |
| | | | a fault condition) |
| NO OVERRIDE | On | Off | PRIMARY |
| NO OVERRIDE | Off | On | SECONDARY |
| NO OVERRIDE | Off | Off | keep last selection |
| | | | (transition step) |

The states of the master indicators 24A, 24B are reported to the redundancy management control software 42 on the central controller 44 and if a failure condition is detected, the central controller 44 via the redundancy management software will designate which redundant component will become the active component. The selection is communicated throughout the system using the selector override message.

The selector override signal 32 can also be used to implement the INHIBIT component selection feature. Under normal operation, however, there is no inhibiting of component selections.

The embodiments described above are examples of structure, systems or methods having elements corresponding to the elements of the invention recited in the claims. This written description may enable those skilled in the art to make and use embodiments having alternative elements that likewise correspond to the elements of the invention recited in the claims. The intended scope of the invention may thus include other structures, systems or methods that do not differ from the literal language of the claims, and may further include other structures, systems or methods with insubstantial differences from the literal language of the claims.

The following is claimed:

1. A control system for a device having a plurality of redundant elements wherein each redundant element has an active state and a standby state, the control system comprising:
a peer-to-peer-like control system that is operative to select the active and standby states of the redundant elements and that comprises a plurality of control components wherein a first control component is associated with a first redundant element and a second control component is associated with a second redundant element; and
a central controller system that is operative to send messages to the first control component and the second control component wherein the messages allow the central controller system to override the selection of states for the redundant elements made by the peer-to-peer-like control system.

2. The control system of claim 1 wherein the first control component and the second control component communicate with each other using a first and second control signal and a first and second indicator signal, the first control signal indicating that the first control component requests that the first redundant element be allowed to enter the active state, the second control signal indicating that the second control component requests that the second redundant element be allowed to enter the active state, the first indicator signal indicating that the first redundant element is in the active state, and the second indicator signal indicating that the second redundant element is in the active state.

3. The control system of claim 1 wherein the central controller system comprises a user interface and wherein a user through the user interface can command the central controller system to select the states for the redundant elements.

4. The control system of claim 1 wherein the central controller system comprises redundancy management software.

5. The control system of claim 4 wherein the redundancy management software comprises redundancy management control software and redundancy management actuator software.

6. The control system of claim 5 wherein the redundancy management actuator software is resident on each redundant element.

7. The control system of claim 6 wherein the redundancy management actuator software resident on the first redundant element communicates with the first control component and the redundancy management actuator software resident on the second redundant element communicates with the second control component.

8. The control system of claim 7 wherein the redundancy management actuator software resident on the first redundant element is operative to send to the first control component an activate signal that allows the central controller system to override the selection of states for the first redundant element made by the peer-to-peer control system and wherein the redundancy management actuator software resident on the second redundant element is operative to send to the second control component an activate signal that allows the central controller system to override the selection of states for the second redundant element made by the peer-to-peer control system.

9. The control system of claim 1 further comprising a generic element that utilizes a function provided by the first and second redundant elements, wherein the generic element is in communication with the central controller system and the first and second redundant elements, wherein the generic element is operative to utilize the function provided by the first redundant element when the generic element is notified that the first redundant element is in the active state, the generic element also being operative to utilize the function provided by the second redundant element when the generic element is notified that the second redundant element is in the active state.

10. The control system of claim 9 wherein the generic element is operative to use the function provided by the first redundant element in response to a master indicator signal received from the first redundant element and wherein the generic element is operative to use the function provided by the second redundant element in response to a master indicator signal received from the second redundant element.

11. The control system of claim 10 wherein the generic element is operative to ignore the master indicator signals received from the redundant elements and select the redundant element whose function is to be used based on a message received from the central controller system.

12. The control system of claim 11 wherein the generic element further comprises redundancy management actuator software that is operative to cause the generic element to ignore the master indicator signals received from the redundant elements and select the redundant element whose function is to be used based on a message received from the central controller system.

13. The control system of claim 10 wherein the generic element is operative to transmit the master indicator signals received from the redundant elements to the central controller system.

14. The control system of claim 9 further comprising a plurality of generic elements.

15. The control system of claim 1 wherein the first and second control components comprise hardware.

16. The control system of claim 1 wherein the first and second control components comprise software.

17. The control system of claim 1 wherein the first and second control components comprise a mixture of hardware and software.

18. A control system for a network system having a plurality of redundant elements wherein each redundant element has an active state and a standby state, the control system comprising:
a peer-to-peer-like control system that is operative to select the active and standby states of the redundant elements; and
a central controller system that is operative to send messages to the peer-to-peer-like control system wherein the messages allow the central controller system to override the selection of states for the redundant elements made by the peer-to-peer-like control system.

19. A system comprising
a first redundant component that is operative to provide a first function used by other components in the system, the first redundant component having an active state in which it provides the first function and a standby state in which it does not provide the first function;
a second redundant component that is also operative to provide the first function, the second redundant component also having an active state in which it provides the first function and a standby state in which it does not provide the first function;
a first control component associated with the first redundant component and a second control component associated with the second redundant component wherein the first control component cooperates with the second control component to determine which of the first redundant component and the second redundant component should be commanded to enter the active state and which should be commanded to enter the standby state; and
an override mechanism that is operative to command one of the first redundant component or the second redundant component to enter the active state wherein the redundant component commanded to enter the active state will enter the active state even if the first control component and the second control component had previously commanded the redundant component to be in the standby state.

20. The system of claim 19 wherein the first control component and the second control component communicate with each other using a first and second control signal and a first and second indicator signal, the first control signal indicating that the first control component requests that the first redundant component be allowed to enter the active state, the second control signal indicating that the second control component requests that the second redundant component be allowed to enter the active state, the first indicator signal indicating that the first redundant component is in the active state, and the second indicator signal indicating that the second redundant component is in the active state.

21. The system of claim 19 wherein the override mechanism comprises a user interface and wherein a user through the user interface can command the override mechanism to select the states for the redundant components.

22. The system of claim 19 wherein the override mechanism comprises redundancy management software.

23. The system of claim 22 wherein the redundancy management software comprises redundancy management control software and redundancy management actuator software.

24. The system of claim 23 wherein the redundancy management actuator software is resident on each redundant component.

25. The system of claim 23 wherein the redundancy management actuator software resident on the first redundant component communicates with the first control component and the redundancy management actuator software resident on the second redundant component communicates with the second control component.

26. The system of claim 25 wherein the redundancy management actuator software resident on the first redundant component is operative to send to the first control component an activate signal that allows the override mechanism to override the selection of states for the first redundant component previously made by the first and second control components and wherein the redundancy management actuator software resident on the second redundant component is operative to send to the second control component an activate signal that allows the override mechanism to override the selection of states for the second redundant component previously made by the first and second control components.

27. The system of claim 19 further comprising a generic element that utilizes a function provided by the first and second redundant components, wherein the generic element is in communication with the override mechanism and the first and second redundant components, wherein the generic element is operative to utilize the function provided by the first redundant component when the generic element is notified that the first redundant component is in the active state, the generic element also being operative to utilize the function provided by the second redundant component when the generic element is notified that the second redundant component is in the active state.

28. The system of claim 27 wherein the generic element is operative to use the function provided by the first redundant component in response to a master indicator signal received from the first redundant component and wherein the generic element is operative to use the function provided by the second redundant component in response to a master indicator signal received from the second redundant component.

29. The system of claim 28 wherein the generic element is operative to ignore the master indicator signals received from the redundant components and select the redundant component whose function is to be used based on a message received from the override mechanism.

30. The system of claim 29 wherein the generic element further comprises redundancy management actuator software that is operative to cause the generic element to ignore the master indicator signals received from the redundant components and select the redundant component whose function is to be used based on a message received from the override mechanism.

31. The system of claim 28 wherein the generic element is operative to transmit the master indicator signals received from the redundant components to the override mechanism.

32. The system of claim 19 wherein the first and second control components comprise hardware.

33. The system of claim 19 wherein the first and second control components comprise software.

34. The system of claim 19 wherein the first and second control components comprise a mixture of hardware and software.

35. A system comprising
a first redundant component that is operative to provide a first function used by other components in the system, the first redundant component having an active state in which it provides the first function and a standby state in which it does not provide the first function;
a second redundant component that is also operative to provide the first function, the second redundant component also having an active state in which it provides the first function and a standby state in which it does not provide the first function;
a peer-to-peer-like control system that is operative to select the active and standby states of the redundant elements; and
an override mechanism that is operative to send messages to the peer-to-peer-like control system wherein the messages allow the override mechanism to override the selection of states for the redundant elements made by the peer-to-peer-like control system.

36. A method for controlling the states of a pair of redundant elements wherein the redundant elements have an active and a standby state, the method comprising the steps of:
commanding the first redundant elements to enter an active state and commanding the second redundant element to enter the standby state using a peer-to-peer-like control system; and
overriding the selection of states made by the peer-to-peer-like control system using a central control element wherein the first redundant element is commanded to enter the standby state and the second redundant element is commanded to enter the active state.

37. The method of claim 36 further comprising the step of:
sending an override message to a generic element that uses a function provided by the redundant elements wherein the override message instructs the generic element as to which redundant element has been commanded by the central control element to enter the active state.

38. The method of claim 36 wherein the overriding step is initiated by a user.

39. The method of claim 36 further comprising the step of providing an inhibit signal wherein the inhibit signal inhibits the peer-to-peer-like control system from commanding the redundant elements to switch states.
